(19) United States
(12) Patent Application Publication
(10) Pub. No.: US 2006/0192550 A1
(43) Pub. Date: Aug. 31, 2006

(54) Current sensor with magnetic toroid single frequency detection scheme

(76) Inventors: David A. Sandquist, St. Paul, MN (US); Andrzej Peczalski, Eden Prairie, MN (US); Dale F. Bermdt, Plymouth, MN (US)

Correspondence Address: Kris T. Fredrick, Esq.;Patent Services, Honeywell International Inc., 101 Columbia Road, Morristown, NJ, 07962, US

(21) Appl. No.: 11/172,732

(22) Filed: Jun. 30, 2005

Related U.S. Application Data
(63) Continuation-in-part of application No. 11/066,788, filed on Feb. 25, 2005.

(51) Int. Cl. G01R 15/20; G01R 15/18

(52) U.S. Cl. 324/117 R

(57) ABSTRACT

A sensor device primarily for sensing current in a primary source, including a primary conductor forming at least one winding on a magnetic material toroid. A secondary source of electrical current from a signal having a frequency f1 forms a plurality of winding on the toroid. An output reader measures the instantaneous loading of the signal passing through the plurality of windings as a function of the primary source current. The device includes a resistor form measuring the resulting voltage or current instantaneous loading for detecting said resulting signal at the frequency twice that of f1 by demodulation of the signal to capture the resulting pulses, the polarity of the primary magnetic field being determined by the polarity of the resulting pulse aligned either at the rising or trailing slope of the applied signal at frequency f1. The primary source of electrical current is AC or DC current.

This is a continuation-in-part of a commonly owned U.S. Patent Application having Ser. No. 11/066,788, filed Feb. 25, 2005, and incorporated herein by reference in its entirety.

### FIELD OF THE INVENTION

The present invention relates to electric current sensors. More particularly, the invention relates to a sensor using a single frequency detection scheme applied to the secondary sensing coil.

### BACKGROUND OF THE INVENTION

There are a number of current sensors used in industrial applications. Example applications are motor control, uninterruptible power supplies, variable speed drives, welding power supplies and the like. There is a trend toward smaller size and lower cost for these current sensors. A number of designs use external magnetic fields, such as, for example, U.S. Pat. No. 3,461,387 which uses three or more coils and it is a device that detects external magnetic fields, not current. The use of a saturated magnetic core has been shown in U.S. Pat. No. 5,239,264 and creates a field current in a coil. U.S. Pat. No. 5,831,432 uses a pair of magneto-impedance elements to cancel out uniform disturbance magnetic fields such as the terrestrial field.

The use of an amorphous wire has been proposed in U.S. Pat. No. 5,994,899. The amplitude of the voltage is asymmetrically varied with a variation in an externally applied magnetic field. A similar use of asymmetrical magneto-impedance is shown in PCT publication WO 02/061445 A1, which is used as a current leakage detector.

U.S. Patent Application Publication No. US 2003/0006765 A1 discloses a sensor coil on an open core, asserting higher accuracy and miniaturization. U.S. Pat. No. 6,512,370 also uses a coil on an open core.

U.S. Pat. No. 5,552,979 determines the measuring current using a high frequency switching circuit which senses the change of flux in the core. However, the circuit is susceptible to transients or drift that can upset the time of the bistable multivibrator and drive the circuit into saturation. The invention proposes circuits to reset the device, but does not prevent it altogether. In one embodiment, there is an offset error from current loading the coil. This is fixed by adding another coil, but at added cost. Further it relies on saturating the material every cycle. This can pass transients into the main current to be sensed, place unwanted transients on the sensor output, and take more energy to completely saturate the material.

U.S. Pat. No. 5,811,965 suggests another method using a transformer signal operating on minor loops and approximating the current to be measured by using the sharpness of the magnetic material's BH curve. However, the approach only crudely approximates the value sensed current since it doesn't sense at the true zero point. Further, the open loop approach is less accurate and more susceptible to variations in material and change over time and temperature than a closed loop approach. The approach is also limited to sensing frequencies two times lower than the AC tickle signal, severely limiting its use in applications requiring fast transient response (<1 microsecond).

U.S. Pat. No. 4,276,510 drives a high frequency AC source to excite the core while an inductance sensor senses the inductances at points adjacent to peaks of the flux wave and the differences are used to provide a feedback current to another coil to null the current to be sensed. This approach uses three windings: one for the current to be sensed, one for the drive, and one for the feedback. This is a higher cost approach and an approach that reduces the number of coils is more desirable.

In traditional Hall effect and magneto-resistive current sensors, the core is used to concentrate flux on a sensor and to partially shield stray fields. Because these sensors have a gap, it is not possible to completely shield external stray fields. It is also more expensive to have a gap and a discrete sensor component. Hall effect devices also have large offset and offset drift errors.

When the loading of coils is used to sense current, the magnitude of the coil's impedance changes with stray field, temperature, part variation and the like. Thus it is not practical to construct a current sensor that relies on an absolute value of the impedance.

In some devices, it is necessary to have some feedback to improve accuracy. This is not a good solution, however, because an additional coil would be required to provide the feedback signal, thus adding to the cost, size, and assembly time.

In a commonly owned, co-pending application having Ser. No. 11/066,788, filed Feb. 25, 2005, the disclosure of which is incorporated herein by reference as if it were fully reproduced herein, detection of electrical current from DC to <1 nsec. is disclosed using a current sensing device that has a rapid response time, high precision response, is small in size, low in cost, an other important properties. That sensor comprises a toroid shaped core having two windings. The first winding contains the primary current of interest. This primary current can be DC or AC. The second winding contains an AC signal that responds such that its instantaneous loading, either as impedance or admittance, corresponds to or is a function of the first or primary current. Typically, only one winding loop is necessary for the primary current of interest. The secondary winding is a plurality of loops, preferably from at least twenty windings. Devices have been made using windings of 30 turns, 100 turns, and 400 turns. The actual number of winding turns is a design variable, depending on the cost and size limitations and the degree of sensitivity and response time needed.

It would be of advantage in the art if a small, inexpensive sensor could be developed that would be limited in response only by the speed that the toroid material can respond to current impulses.

Yet another advantage would be if a sensor could be provided that is capable of sensing both DC and AC current of faster than one nsec.

Another advantage would be if the sensor could discriminate between currents of positive and negative polarities.

It would be another advance in the art if a sensor could be provided with closed loop control by selection of an appropriate frequency in the secondary coil.

Other advantages will appear hereinafter.

### SUMMARY OF THE INVENTION

It has now been discovered that the above and other advantages of the present invention may be obtained in the following manner. Specifically, the present invention provides a current sensing device that has a rapid response time, has a high precision response, is small in size, low in cost, an other important properties.

In its simplest form the present invention comprises a sensor device using a magnetic material having nonlinear magnetic properties and having an ambient magnetic flux. A signal conductor provides an applied electric signal having a frequency f1 with a rising and falling slope. The signal is couple to the magnetic material to produce a resulting signal pulse either on the rising or falling slope of the signal. The resulting signal is detected at the frequency twice that of f1 using a synchronous demodulation of the signal to capture the resulting pulses. The polarity of the primary magnetic field is determined by the polarity of the resulting pulse aligned either at the rising or trailing slope of the applied signal at frequency f1.

The magnetic material may be formed in a shape with two ends and an open portion with a gap between the two ends. The device may include a primary conductor for carrying a primary current coupled to the magnetic material to change the magnetic flux of the magnetic material and produce the resulting signal. The detection of the resulting signal creates a signal related to the primary current's magnitude and polarity. Alternatively, the magnetic material may be in the shape of a toroid and primary and signal conductors are configured as winding on the toroid.

In either embodiment, a feedback loop is provided for carrying resulting signal pulses, which are demodulated to DC and carried to the secondary conductor to cancel the magnetic field created by the primary current to thereby form a closed loop device. One way to close the loop is to connect the signal from the open loop circuit and sum it with an applied signal having a frequency f1.

In another embodiment, the loop is closed by connecting the signal from the open loop circuit to a fixed frequency pulse width modulation circuit where the pulse width modulation circuit generates signal f1 and it has a duty cycle proportional to the feedback error signal. The closed loop frequency response is adapted to operate above the low end of a transformer effect frequency. This provides a response from DC to the fastest response of the magnetic material operating as an open loop transformer.

The system gain may be placed before the final demodulation state to nearly eliminate offset and offset drift errors in the electronics.

It is intended that the applied signal having frequency f1 may be a voltage signal, whereby the resulting signal is a current, or f1 may be a current signal, whereby the resulting signal is a voltage.

The magnetic material of the present invention has an amorphous core magnetic material. Preferred is a magnetic material having an hysteresis saturation point at least 50 times larger than the coercivity of the material. One such material is Metglas® 2714, available from the Metglas Inc. It is a cobalt based, ultrahigh permeability magnetic alloy. Other materials are also useful, such as at least some forms of permalloy and ferrite cores.

### BRIEF DESCRIPTION OF THE DRAWINGS

For a more complete understanding of the invention, reference is hereby made to the drawings, in which:

FIG. 1 is a circuit diagram showing one embodiment of the present invention;

FIG. 2 is a graphical representation of the results from the device of FIG. 1, showing several output traces;

FIG. 3 is a graphical illustration of the B-H curve for a material used in the present invention;

FIGS. 4a and 4b are graphical representations similar to FIG. 2, with a sine wave and a triangle wave being applied respectively;

FIG. 5 is a circuit schematic of one form of the present invention;

FIG. 6 is a circuit schematic when the invention employs a pulse width modulated voltage drive;

FIG. 7 is a circuit schematic of the larger circuit employing features of the present invention;

FIG. 8 is a graphic representation of a DC transfer function of the present invention and the linearity error when configured as a ±10 amp sensor;

FIG. 9 is a graph showing the AC response of the circuit; and

FIG. 10 is a graph showing the sensor response to a highly non-uniform stray magnetic field generated by a nearby conductor.

### DETAILED DESCRIPTION OF THE PREFERRED EMBODIMENT

The present invention provides for substantial improvements in small current measuring devices. Specifically, the device of this invention operates based on the way the magnetic properties of a toroid core change with current applied to turns off wire wrapped around the core. Applied current, called the primary current or current being sensed, generates a magnetic field that becomes trapped in the core. This magnetic field starts to saturate the core. Saturation changes the AC losses and inductance of a coil upon the core. This change in core properties is detected as a change in impedance looking into a second coil wrapped around the core.

In prior art Hall effect, fluxgate, and magneto-resistive current sensors, the core is used to concentrate flux on a sensor and to partially shield stray fields. In the present invention, by looking at how the impedance, or inversely the admittance, in the core changes with applied current, the core itself becomes the sensor, resulting in a cost savings. Moreover, without a gap for a Hall effect, fluxgate, or magneto-resistive sensor, external stray fields are completely shielded. Further, a toroid without a gap removes the process step to cut a gap in the toroid, which reduces cost and complexity.

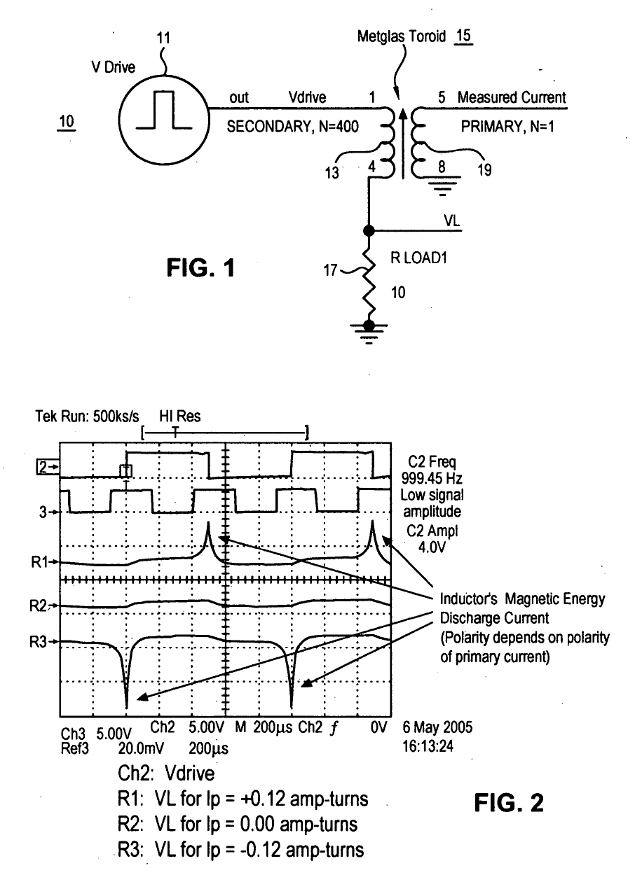

A core circuit is shown in FIG. 1, 10 generally, with A square wave voltage drive 11 is applied to a 400 turn coil 13 on an amorphous toroidal core 15. The resulting current in core 15 is measured across resistor RLOAD1 17. The current to be measured is applied through one turn 19 on the core 15.

FIG. 2 illustrates an actual oscilloscope waveform of the circuit in FIG. 1. Trace 2 (top trace) is the voltage drive applied to the 400 turn coil. R1 shows the voltage across RLOAD1 for +0.12 amp-turns on the primary. R2 shows the voltage across for +0.0 amp-turns on the primary. Trace R3 shows the voltage cross RLOAD1 for −0.12 amp-turns on the primary. Since RLOAD is a resistor in series with the 400 turn coil, this voltage is proportional to the current in the coil. In the case of a positive primary current, there is positive current spike aligned to the falling slope of the drive voltage. For a negative primary current, there is negative current spike aligned to the rising slope of the drive voltage. For zero primary current, there is no spike. By synchronous detection or demodulation (Trace 3) at twice the drive frequency (2×f1) a DC level results that is related in magnitude and polarity to the applied primary current.

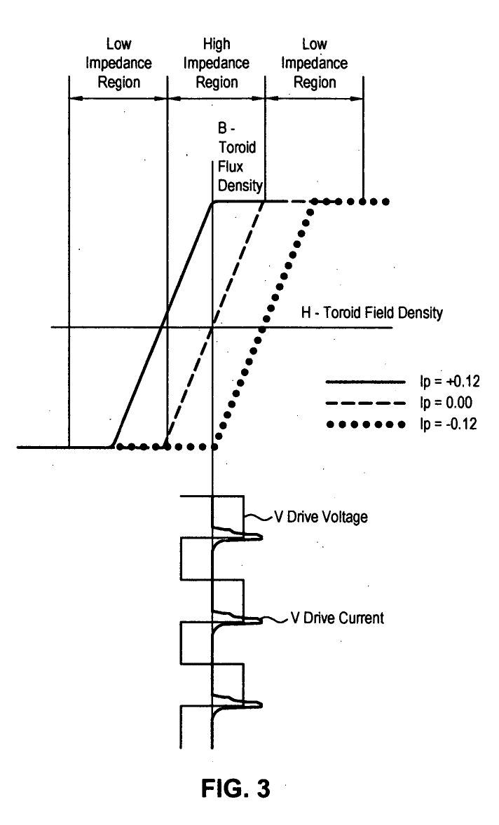

FIG. 3 illustrates the reason for the current spikes/pulses shown in FIG. 2. The amorphous material that forms the toroid is shown in the B-H curve, where B is the core's magnetic flux density and H is the core' magnetic field intensity. The curve has been simplified for purposes of illustration. The flat parts of the curve, at zero slope, are areas of low impedance. The sloped area is an area of high impedance. The B-H curve moves left to right, depending on the primary current polarity. The current generates magnetic field. When the AC voltage drive is applied to the 400 turn coil, part of the waveform sees high impedance and part sees low impedance. The current spikes for the low impedance region since the voltage attempts to remain fixed. This is shown in FIG. 3 in the orthogonal trace below the B-H curve.

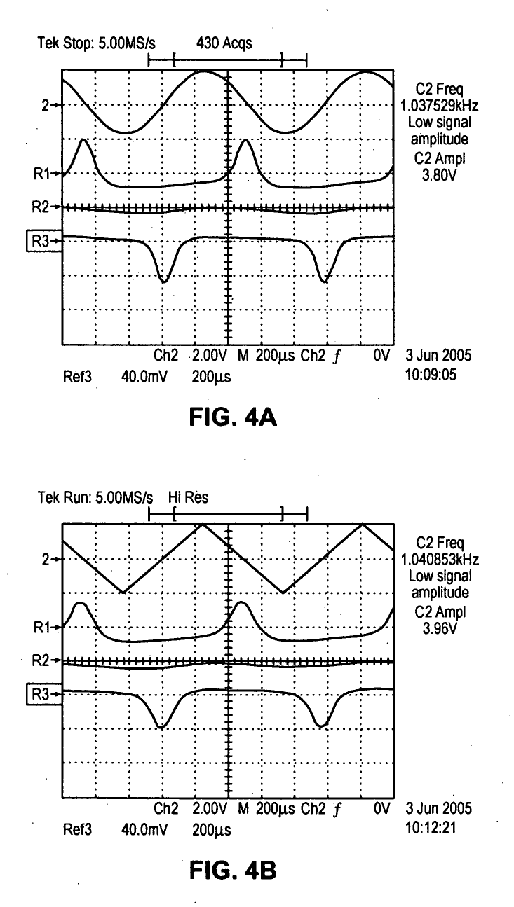

The circuit in FIG. 1 illustrates the use of a square wave. The circuit will, however, show similar pulse responses when a sine wave is applied, shown in FIG. 4a, and when a triangle wave is applied, shown in FIG. 4b. While experimental work to date has been primarily with square waves, FIGS. 4a and 4b illustrate that other wave forms are suitable for the present invention. One advantage of a sine wave would be to reduce capacitive feed through since higher frequency harmonics are not present.

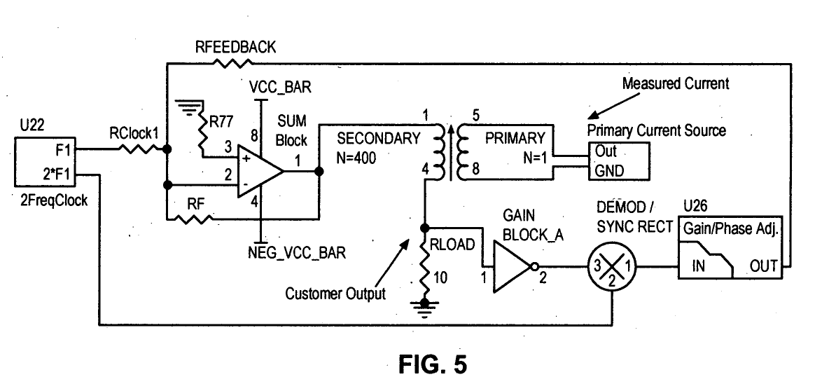

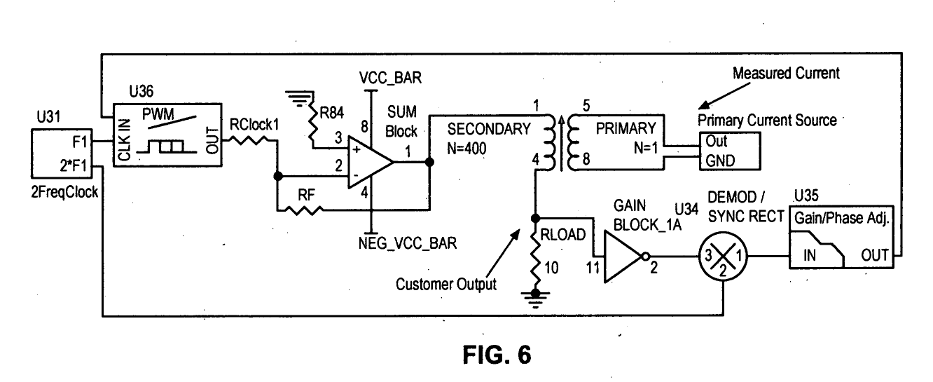

FIG. 5 is a circuit schematic where U22 is a clock circuit that can be realized with discrete logic, a CPLD, a microprocessor or analog electronics. The clock circuit generates a frequency f1 and a synchronous rectification clock frequency at twice f1. F1 is fed to an amplifier, identified as the sum block, where it then applies that voltage to a 400 turn coil on an amorphous toroidal core. The current in the coil is measured using resistor RLOAD. This signal is amplified by Gain Block A and then demodulated via synchronous rectification using the clock signal at twice the f1 frequency. This signal is then modified for gain and phase through U26. The signal after the gain/phase block is the open loop response of the sensor or it can be applied to the sum block to provide closed loop control. FIG. 6 is a circuit schematic that is similar to FIG. 5 and which has the additional feature of a pulse width modulated (PMW) voltage drive on f1 and the feedback given by the equivalent DC level caused by variation in the pulse width.

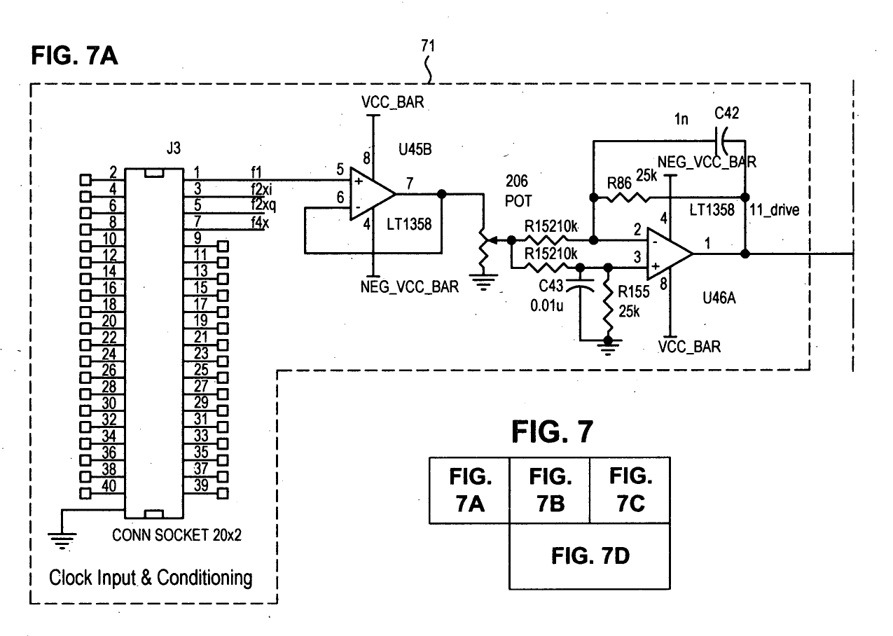

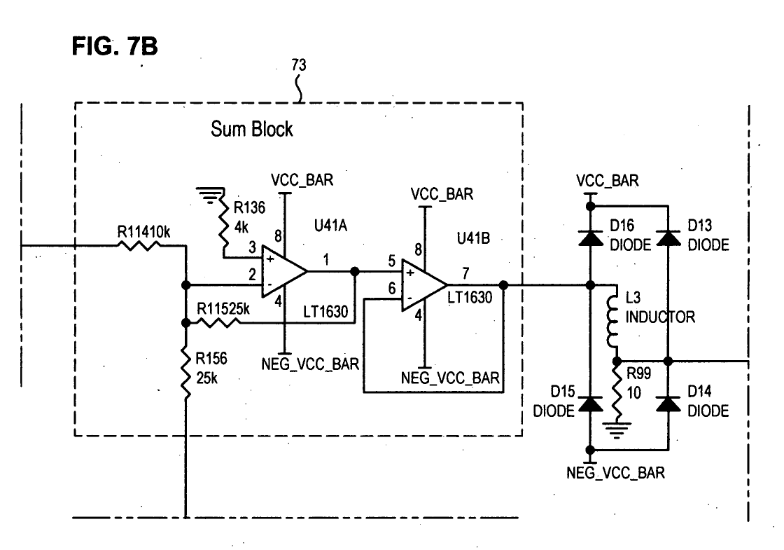

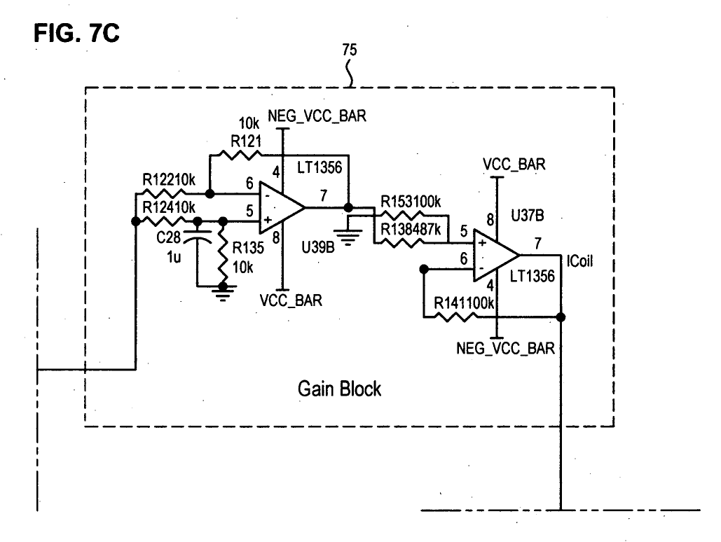

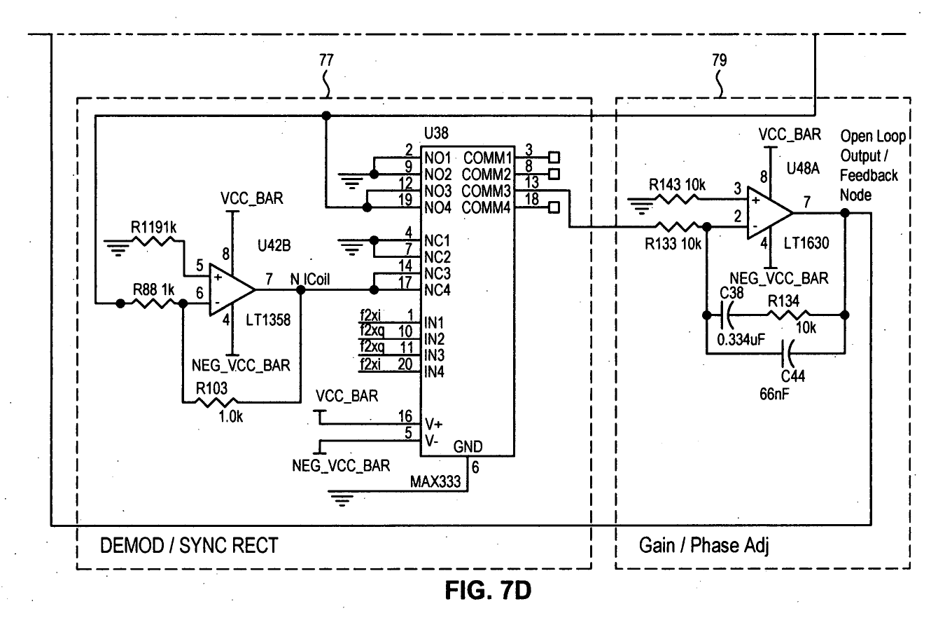

FIG. 7 is a more detailed or complete schematic of the single frequency circuit used in the present invention to produce a signal related in magnitude and polarity and phase to the primary current signal being measured. The schematic includes a clock in put and conditioning block 71, a sum block 73. and a gain block 75. the demodulation or synchronous rectification circuit 77 and the gain/phase adjustment circuit 79. The clock circuit for f1 and 2*f1 is not shown.

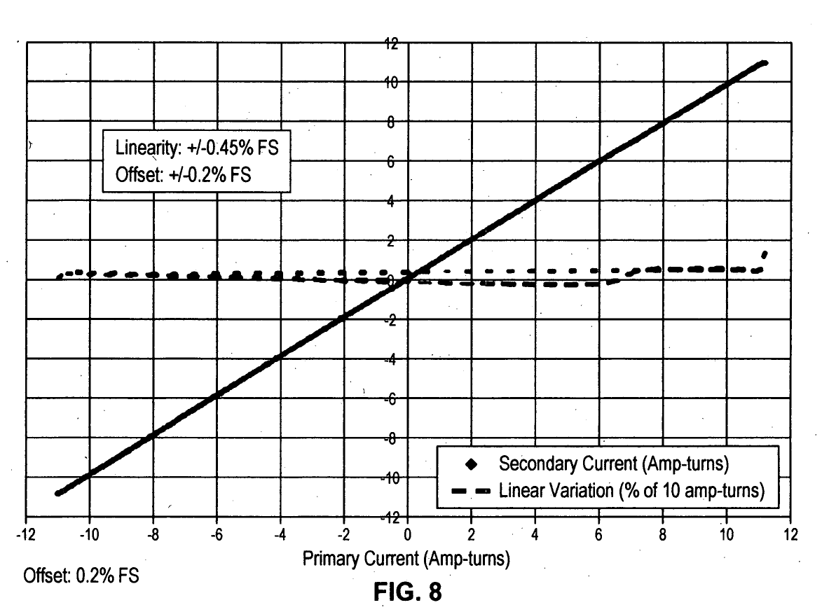

FIG. 8 is a graphical representation of the DC transfer function when configured as a sensor linear over the range of ±10 amp-turns along with the variation of the output from linearity as a percentage of 10 amps. As shown in FIG. 8, the offset is less than 0.2% FS.

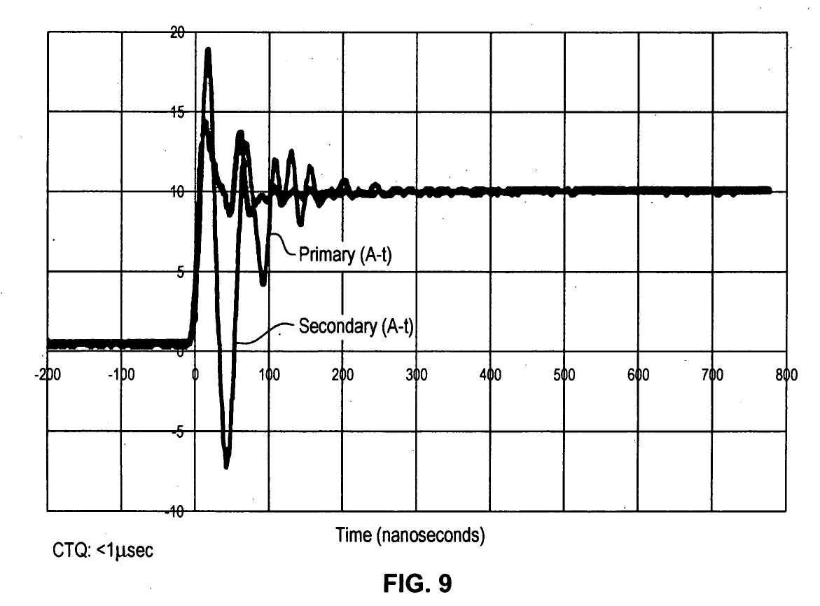

FIG. 9 shows the AC response of the sensor to a 10 amp-turn pulse on the primary conductor. Note that the secondary current, which is the sensor output, mirrors the rise of the primary current within about a nanosecond. The efficacy of the present invention is shown by illustrating the pulse response of the circuit, which response is faster than 300 nanoseconds.

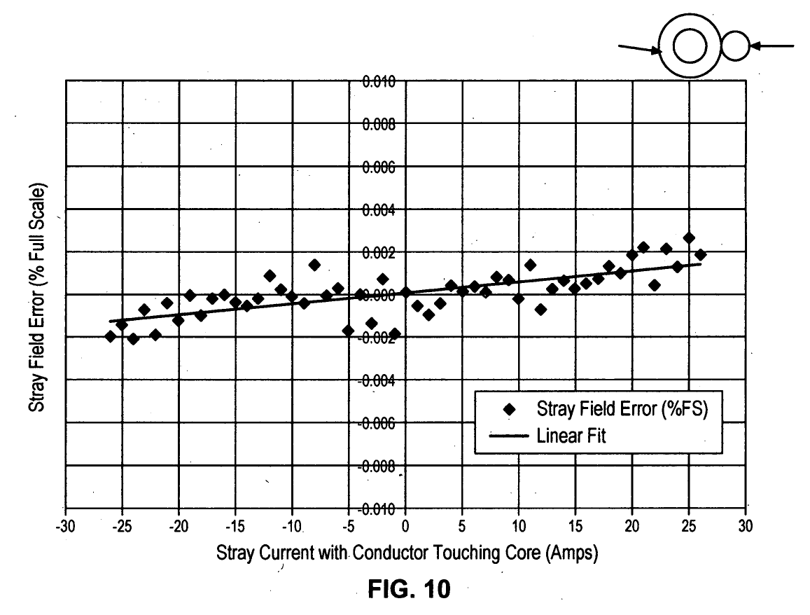

FIG. 10 shows the sensor's insensitivity to stray magnetic field. In this case a copper conductor with −26 to +26 amps was placed next to the sensor so they are in contact. The conductor was placed for maximum magnetic field disturbance and nonuniformity. The error signal was recorded and is plotted here in FIG. 10. For 25 amps directly next to a 10 amp sensor, the maximum error was 0.0013% of full scale (10 amps). That is only 13 parts per million variation in output when a current two and a half times larger than the full scale value is placed next to the sensor. Traditional gapped core and no core current sensors have sensitivities to stray magnetic field from a conductor from 500 to 5000 times larger than this.

It should be noted that the devices of the present invention can readily have many configurations. Of particular interest are configurations that are integrated with Mechanical Electrical Microsystem integrated circuits or circuit board technologies, and such are within the scope of this invention.

The sensor has been demonstrated with f1 frequencies of 125 Hz to 40 kHz. However, the particular drive frequency is a design variable dependent upon many constraints including desired performance, number of secondary turns, core material, core dimensions, system gain, system phase requirements and others.

While particular embodiments of the present invention have been illustrated and described, it is not intended to limit the invention, except as defined by the following claims.

1. A sensor device comprising:
a magnetic material having nonlinear magnetic properties within an ambient magnetic flux;
a signal conductor carrying an applied electric signal having a frequency f1 and a rising and falling slope, said signal being coupled to said magnetic material with said ambient magnetic flux to produce a resulting signal pulse either on the rising slope or falling slope of the applied electrical signal; and
electrical means for detecting said resulting signal at the frequency twice that of f1 using a demodulation of the signal to capture the resulting pulses, the polarity of the primary magnetic field being determined by the polarity of the resulting pulse aligned either at the rising or trailing slope of the applied signal at frequency f1.

2. The device of claim 1, wherein said magnetic material and signal conductor are integrated with a MEMS integrated circuit or circuit board.

3. The device of claim 1, wherein said magnetic material has two ends and an open shape with a gap between said two ends.

4. The device of claim 3, wherein said magnetic material and said signal conductor are integrated with a MEMS integrated circuit or circuit board.

5. The device of claim 1, which further includes a primary conductor for carrying a primary current coupled to said magnetic material having nonlinear magnetic properties to change the magnetic flux of said magnetic material and produce said resulting signal; and said electrical means for detecting said resulting signal and creates a signal related to the primary current's magnitude and polarity.

6. The device of claim 5, wherein said magnetic material and said primary and signal conductors are integrated with a MEMS integrated circuit or circuit board.

7. The device of claim 5, wherein said magnetic material is in the shape of a toroid.

8. The device of claim 7, wherein said primary and signal conductors are configured as windings on said toroid.

9. The device of claim 5, which includes a feedback loop for carrying resulting signal pulses demodulated to DC back to said secondary conductor to cancel the magnetic field created by said primary current to thereby form a closed loop device.

10. The device of claim 9, wherein said loop is closed by connecting the signal from the open loop circuit and summing it with an applied signal having a frequency f1.

11. The device of claim 9, wherein said loop is closed by connecting the signal from the open loop circuit to a fixed frequency pulse width modulation circuit where said pulse width modulation circuit generates signal f1 and it has a duty cycle proportional to the feedback error signal.

12. The device of claim 9, wherein said closed loop frequency response operates above the low end of a transformer effect frequency to thus provide a response from DC to the fastest response of the magnetic material operating as an open loop transformer.

13. The device of claim 9, wherein the system gain is placed before the final demodulation stage to reduce the electronics offset and offset drift errors proportional to that gain.

14. The device of claim 1 wherein said applied electrical signal having frequency f1 is a voltage signal whereby said resulting signal is current.

15. The device of claim 1 wherein said applied electrical signal having frequency f1 is a current signal whereby said resulting signal is voltage.

16. A sensor device comprising:
magnetic material means for having nonlinear magnetic properties within an ambient magnetic flux;
signal conductor means for carrying an applied electric signal having a frequency f1 and a rising slope and falling slope, said signal being coupled to said magnetic material with said ambient magnetic flux to produce a resulting signal pulse on said rising or falling slope of the applied electrical signal; and
electrical means for detecting said resulting signals at the frequency twice that of f1 using demodulation means of the signals for capturing the resulting signal pulses, the polarity of the primary magnetic filed being determined by the polarity of the resulting pulse aligned either at the rising or trailing slope of the applied signal frequency signal f1.

17. The device of claim 16, wherein said magnetic material means and signal conductor means are integrated with a MEMS integrated circuit or circuit board means.

18. The device of claim 16, wherein said magnetic material has two ends and an open shape with a gap between said two ends.

19. The device of claim 18, wherein said magnetic material means and signal conductor means are integrated with a MEMS integrated circuit or circuit board means.

20. The device of claim 16, which further includes primary conductor means for carrying a primary current coupled to said magnetic material means having nonlinear magnetic properties to change the magnetic flux of said magnetic material means and produce said resulting signal; and
said electrical means for detecting said resulting signal and creates a signal related to the primary current's magnitude and polarity.

21. The device of claim 16, wherein said magnetic material means, said primary conductor means and said signal conductor means are integrated with a MEMS integrated circuit or circuit board means.

22. The device of claim 16, wherein said magnetic material means is in the shape of a toroid.

23. The device of claim 22, wherein said primary and signal conductor means are configured as windings on said toroid.

24. The device of claim 19, which includes a feedback loop means for carrying resulting signal pulses demodulated to DC back to said secondary conductor means to cancel the magnetic field created by said primary current to thereby form a closed loop device.

25. The device of claim 24, wherein said loop is closed by connecting the signal from the open loop circuit and summing it with an applied signal having a frequency f1.

26. The device of claim 24, wherein said loop is closed by connecting the signal from the open loop circuit to a fixed frequency pulse width modulation circuit where said pulse width modulation circuit generates signal f1 and has a duty cycle proportional to the feedback error signal.

27. The device of claim 24, wherein said closed loop frequency response operates above the low end of a transformer effect frequency to thus provide a response from DC to the fastest response of the magnetic material operating as an open loop transformer.

28. The device of claim 24, wherein the system gain is placed before the final demodulation stage to reduce the electonics offset and offset drift errors proportional to that gain.

29. The device of claim 16, wherein said applied electrical signal having frequency f1 is a voltage signal whereby said resulting signal is current.

30. The device of claim 16, wherein said applied compound electrical signal having frequency f1 is a current whereby said resulting signal is voltage.
